(19) United States
(12) Patent Application Publication
(10) Pub. No.: US 2026/0143837 A1
(43) Pub. Date: May 21, 2026

(54) ELECTRONIC DEVICE

(71) Applicant: STMicroelectronics International N.V., Geneva (CH)

(72) Inventors: Arthur ARNAUD, La Tronche (FR); Sofia BOUGHALEB, Grenoble (FR)

(73) Assignee: STMicroelectronics International N.V., Geneva (CH)

(21) Appl. No.: 19/388,294

(22) Filed: Nov. 13, 2025

(30) Foreign Application Priority Data
Nov. 15, 2024 (FR) FR2412495

(51) Int. Cl. H10F 39/00; H10F 30/223

(52) U.S. Cl. CPC H10F 39/8037; H10F 30/223

(57) ABSTRACT

An optoelectronic device includes a pixel having a pinned photodiode and a bipolar transfer transistor. The pinned photodiode and the bipolar transfer transistor are formed inside and on top of a same semiconductor substrate made of a group III-V material. A same doped semiconductor layer forms the collector of the bipolar transfer transistor and the cathode of the photodiode.

### PRIORITY CLAIM

This application claims the priority benefit of French Application for Patent No. FR2412495, filed on Nov. 15, 2024, the content of which is hereby incorporated by reference in its entirety to the maximum extent allowable by law.

### TECHNICAL FIELD

The present disclosure generally concerns electronic devices and, more particularly, optoelectronic devices comprising a photodiode.

### BACKGROUND

Optoelectronic devices include image sensor devices. Image sensors generally have a plurality of pixels, each comprising a photosenstive element, for example a photodiode, capable of capturing an optical radiation and of transforming it into an electrical signal. Each pixel generally comprises a control circuit associated with the pixel, comprising a plurality of transistors. It is referred to as a 3T pixel where there are three transistors in the control circuit, or as a 4T pixel where there are four transistors in the control circuit.

### SUMMARY

An embodiment provides an optoelectronic device comprising a pixel, the pixel comprising a pinned photodiode and a bipolar transfer transistor, the pinned photodiode and the bipolar transfer transistor being formed inside and on top of a same first semiconductor substrate made of a group III-V material, wherein a same first doped semiconductor layer forms the collector of the bipolar transfer transistor and the cathode of the pinned photodiode.

Another embodiment provides a method of manufacturing an optoelectronic device comprising a pixel, the pixel comprising a pinned photodiode and a bipolar transfer transistor, the pinned photodiode and the bipolar transfer transistor being formed inside and on top of a same first semiconductor substrate made of a group III-V material, wherein a same first doped semiconductor layer forms the collector of the bipolar transfer transistor and the cathode of the pinned photodiode.

According to an embodiment, the pinned photodiode comprises a second doped semiconductor layer forming the anode of the pinned photodiode, and a third doped semiconductor layer of the same conductivity type as the second doped semiconductor layer, the first doped semiconductor layer being located between the second and third doped semiconductor layers, the first doped semiconductor layer resting on a first surface of the second doped semiconductor layer.

According to an embodiment, the photodiode further comprises a fourth doped semiconductor layer more heavily doped than the second doped semiconductor layer, the fourth doped semiconductor layer covering a peripheral portion of the first surface of the first doped semiconductor layer and not covering a central portion of the first surface of the first doped semiconductor layer, the third doped semiconductor layer covering the central portion of the first surface of the first doped semiconductor layer.

According to an embodiment, the pixel comprises a fifth doped semiconductor layer resting on the third doped semiconductor layer, the fifth doped semiconductor layer being separated from the first doped semiconductor layer by the third doped semiconductor layer, the fifth doped semiconductor layer forming the emitter of the transistor and the first doped semiconductor layer forming the collector of the transistor.

According to an embodiment, the pixel comprises a passivation region made of one of a charged oxide or a semiconductor material doped with zinc atoms or beryllium atoms, the passivation region surrounding the first doped semiconductor layer.

According to an embodiment, the device comprises at least two pixels, the first doped semiconductor layer being common to a plurality of pixels, the portions of the first doped semiconductor layer corresponding to each pixel being separated by passivation regions.

According to an embodiment, the pixel comprises a wall extending in the passivation region, so as to surround the first doped semiconductor layer, the wall being configured to be biased.

According to an embodiment, the pixel comprises a layer made of NiOx located between the third doped semiconductor layer and a contact pad.

According to an embodiment, the device comprises a control circuit configured to control the pixel, wherein the bipolar transistor is a transfer transistor of said control circuit.

According to an embodiment, the device comprises a second semiconductor substrate on top and inside of which transistors of the control circuit are formed, wherein the first and second semiconductor substrates are bonded to each other by molecular bonding.

Another embodiment provides a method of controlling the device such as previously described, the method comprising a storage mode, in which the third doped semiconductor layer receives a negative voltage, and a readout mode, in which the third doped semiconductor layer receives a positive voltage.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of an electronic device comprising a pixel;

FIG. 2 schematically shows the circuit of a pixel;

FIG. 3A to 3E show structures resulting from steps of a method of manufacturing the device of FIG. 1;

FIG. 4 shows another embodiment of an electronic device comprising a pixel;

FIG. 5 shows another embodiment of an electronic device comprising a pixel;

FIG. 6 shows another embodiment of an electronic device comprising a pixel;

FIG. 7 shows another embodiment of an electronic device comprising a pixel;

FIG. 8 shows another embodiment of an electronic device comprising a pixel;

FIG. 9 shows another embodiment of an electronic device comprising a pixel;

FIG. 10 shows another embodiment of an electronic device comprising a pixel;

FIG. 11 shows another embodiment of an electronic device comprising a pixel;

FIG. 12 is a cross-section view of FIG. 11;

FIG. 13 shows an embodiment of an electronic device comprising several pixels;

FIG. 14 is a perspective view with transparence of the pixel of FIG. 11 used for a first simulation;

FIG. 15 is a three dimensional view showing the evolution of the concentration of free charges in a central region of the pixel for the first simulation;

FIG. 16 is a top view showing, in light intensity level, the evolution of the concentration of free charges in the central region of the pixel for the first simulation;

FIG. 17 is a perspective view with transparence of the pixel of FIG. 11 used for a second simulation;

FIG. 18 is a three dimensional view showing the evolution of the concentration of free charges in a region of the pixel for the second simulation;

FIG. 19 is a top view showing, in light intensity level, the evolution of the concentration of free charges in the central region of the pixel for the second simulation;

FIG. 20A to FIG. 20M show structures resulting from steps of a method of manufacturing the device of FIG. 13; and

FIG. 21A to FIG. 21F show structures resulting from steps of another method of manufacturing the device of FIG. 13.

### DETAILED DESCRIPTION

The same elements have been designated by the same references in the various figures. In particular, structural and/or functional elements common to the various embodiments may have the same references and may have identical structural, dimensional and material properties.

For the sake of clarity, only those steps and elements that are useful for understanding the described embodiments have been shown and are described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the figures.

Unless otherwise specified, the expressions “about”, “approximately”, “substantially”, and “of the order of” mean to within 10% or 10°, preferably to within 5% or 5°.

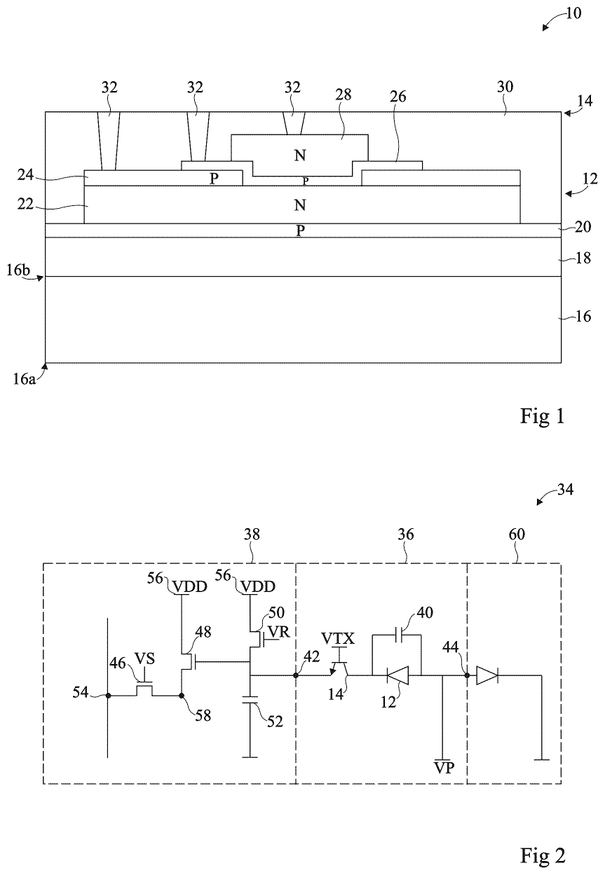

FIG. 1 shows an example of an electronic device comprising a pixel 10. More specifically, FIG. 1 shows a portion of pixel 10. In particular, FIG. 1 shows a photodiode 12 and a transfer transistor 14. Transistor 14 and photodiode 12 are formed based on group III-V semiconductor materials.

Pixel 10 comprises a semiconductor substrate 16. Substrate 16 is made, for example, of: a type-III-V semiconductor alloy, germanium, or a semiconductor alloy comprising germanium. By type-III-V semiconductor material, there is meant a material formed of one or more elements from column III and column V of Mendeleev's periodic table. Column-III elements are boron, aluminum, gallium, indium, thallium, and nihonium. Column-V elements are nitrogen, phosphorus, arsenic, antimony, bismuth, and moscovium. For example, substrate 16 is made of gallium arsenide (GaAs). Substrate 16 comprises a lower surface 16a and an upper surface 16b.

Pixel 10 comprises a layer 18. Layer 18 is made of a semiconductor material, for example made of the same material as substrate 16. Layer 18 is, for example, an epitaxial layer. Layer 18 covers, and is preferably in contact with, the upper surface 16b of substrate 16. Layer 18 preferably entirely covers the portion of substrate 16 located in pixel 10, preferably entirely covers substrate 16. Layer 18 is, for example, a buffer layer enabling to relieve the mechanical stress due to lattice mismatches between layers of materials.

Pixel 10 comprises a layer 20. Layer 20 is made of a semiconductor material, for example made of the same material as substrate 16. Layer 20 is, for example, an epitaxial layer. Layer 20 covers, and is preferably in contact with, the upper surface of layer 18. Layer 20 preferably entirely covers the portion of layer 18 located in pixel 10. Layer 20 is doped with a first conductivity type, for example type P. Layer 20 is heavily doped. For example, the dopant concentration of layer 20 is greater than 10¹⁷ atoms/cm³.

Pixel 10 comprises a layer 22. Layer 22 is made of a photosensitive semiconductor material, for example made of the same material as layer 20. Layer 22 is configured to be photosensitive to a specific operating wavelength range. Layer 22 is, for example, an epitaxial layer. Layer 22 covers, and is preferably in contact with, the upper surface of layer 20. Layer 22 partially covers the portion of layer 20 located in pixel 10. A portion of layer 20 located in pixel 10 is thus preferably not covered by layer 22. Layer 22 is doped with a second conductivity type, opposite to the first conductivity type, for example type N. For example, the doping concentration of layer 22 is in the range from 10¹⁵ atoms/cm³ to 10¹⁸ atoms/cm³.

Pixel 10 comprises a layer 24. Layer 24 is made of a semiconductor material, for example made of the same material as layer 22. Layer 24 is, for example, an epitaxial layer. Layer 24 covers, and is preferably in contact with, the upper surface of layer 22. Layer 24 covers a peripheral portion of the upper surface of layer 22. Layer 24 is thus in contact with a peripheral portion of the upper surface of layer 22. The central portion of the upper surface of layer 22 is thus not covered by layer 24. The peripheral portion of the upper surface of layer 22 covered by layer 24 surrounds the central portion of the upper surface of layer 22. Layer 24 is doped with the first conductivity type, for example type P. Layer 24 is heavily doped. For example, the dopant concentration of layer 24 is substantially equal to the dopant concentration of layer 20, for example greater than 10¹⁷ atoms/cm³.

The doping of layers 20, 22, and 24 is selected so that the layer 22 sandwiched between layers 20 and 24 is depleted.

Pixel 10 comprises a layer 26. Layer 26 is made of a semiconductor material, for example made of the same material as layer 24. Layer 26 is, for example, an epitaxial layer. Layer 26 covers, and is preferably in contact with, the central portion of the upper surface of layer 22. Preferably, layer 26 covers, and is in contact with, a portion of the upper surface of layer 24, preferably the portion closest to the central portion of layer 22. Preferably, layer 24 is not entirely covered by layer 26. Layer 26 is doped with the first conductivity type, for example type P. For example, the dopant concentration of layer 26 is in the range from 10¹⁶ atoms/cm³ to 10¹⁸ atoms/cm³. Layer 26 is configured not to absorb light. Layer 26 is configured to have a bandgap sufficiently different from the bandgap of layer 24 for charges to predominantly flow through layer 26 and not through layer 24.

Pixel 10 comprises a layer 28. Layer 28 is made of a semiconductor material, for example made of the same material as layer 26. Layer 28 is, for example, an epitaxial layer. Layer 28 covers, and is preferably in contact with, the upper surface of layer 26. Layer 28 covers at least one region of the portion of layer 26 covering the central portion of layer 22. Thus, layer 28 faces at least one region of the central portion of layer 22. Preferably, layer 28 covers a region of layer 26 covering layer 24. Preferably, layer 26 is not entirely covered by layer 28. Layer 28 is doped with the second conductivity type, for example type N. Layer 28 is heavily doped. For example, the dopant concentration of layer 28 is substantially equal to the dopant concentration of layer 20, for example greater than 10¹⁸ atoms/cm³.

The pixel further comprises a layer 30. Layer 30 is a passivation layer. Layer 30 covers the upper surface of the structure. Layer 30 thus covers the upper surfaces of layers 20, 24, 26, 28 and the lateral surfaces of layers 22, 24, 26, 28. Layer 30 is, for example, made of silicon nitride.

Pixel 10 further comprises contact pads 32 crossing layer 30 so as to reach, and bias, portions of the pixel. FIG. 1 shows three contact pads 32, including a pad in contact with layer 24, a pad in contact with layer 26, and a pad in contact with layer 28. Preferably, layer 20 is biased to the same voltage as layer 24.

Layers 20, 22, 24 form photodiode 12. The photodiode is a planar photodiode. Photodiode 12, formed by layers 20, 22, 24, is a pinned photodiode. More specifically, layer 22 forms the cathode of photodiode 12. Layer 20 is the anode of photodiode 12. Layer 24 is a layer pinning photodiode 12. Thus, layer 22 is fully depleted. Photodiode 12 is preferably configured to be illuminated from the lower surface 16a of the substrate.

Further, layers 22, 26, 28 form transfer transistor 14. Transistor 14 is a bipolar transistor, for example an NPN bipolar transistor. More specifically, layer 22 forms the collector of transistor 14. Layer 26 forms the base of transistor 14. Layer 28 forms the emitter of transistor 14. Thus, the cathode of photodiode 12 and the emitter of transistor 14 are connected.

FIG. 2 schematically shows a circuit 34 of a pixel. More specifically, circuit 34 corresponds to a circuit of the pixel 10 of FIG. 1. Thus, circuit 34 comprises photodiode 12 and bipolar transistor 14.

Pixel 10 comprises, for example, two assemblies of components. Pixel 10 comprises a first component assembly 36 and a second component assembly 38. Component assemblies 36 and 38 are, for example, formed on separate substrates. Component assemblies 36 and 38 are formed on substrates made of different materials.

Assembly 36 comprises photodiode 12, bipolar transistor 14, and a capacitor 40. The emitter of transistor 14, formed by layer 28, is coupled, preferably connected, to a node 42. The base of transistor 14, formed by layer 26, is configured to be biased to a voltage VTX. The collector of transistor 14 is connected to the cathode of photodiode 12, the collector and the cathode being formed by layer 22. The anode of photodiode 12 is coupled, preferably connected, to a node 44. Capacitor 40 illustrates the charge storage capacity of layer 22. The anode of photodiode 12 is, for example, configured to be biased by a voltage VP.

The components of assembly 36 are formed on top of and inside a single semiconductor substrate. Said semiconductor substrate is of group III-V type. The semiconductor regions of the components of assembly 36 are preferably made of a group III-V material.

Assembly 38 comprises the other components of the photodiode readout circuit. In the example of FIG. 2, assembly 38 comprises three transistors 46, 48, 50, and a capacitor 52 illustrating the charge storage capacity. Transistor 46 is a selection transistor. Transistor 48 is a power supply transistor. Transistor 50 is a reset transistor.

Transistors 46 and 48 are coupled between a node 54 and a node 56 of application of a power supply voltage VDD. More specifically, a conduction terminal of transistor 46 is coupled, preferably connected, to node 54 and another conduction terminal of transistor 46 is coupled, preferably connected, to node 58. A conduction terminal of transistor 48 is coupled, preferably connected, to node 58 and another conduction terminal of transistor 48 is coupled, preferably connected, to node 56. A control terminal of transistor 46 is configured to be biased to a selection voltage VS. A control terminal of transistor 48 is coupled, preferably connected, to node 42.

Transistor 50 is coupled between node 56 and node 42. In other words, one conduction terminal of transistor 50 is coupled, preferably connected, to node 56 and another conduction terminal of transistor 50 is coupled, preferably connected, to node 42. A control terminal of transistor 50 is configured to be biased to a reset voltage VR.

The components of assembly 38 are formed on a same substrate, for example a silicon substrate. The components of assembly 38 are, for example, implemented in CMOS technology. Assemblies 36 and 38 are coupled at node 42, for example by a conductive element, for example by an electric wire. The substrate on which the components of assembly 38 are formed is bonded to the substrate on which assembly 36 is formed, for example by molecular bonding.

Circuit 34 comprises, for example, a filter 60. Filter 60 is formed, for example, on the same substrate as assembly 36, on the same substrate as assembly 38, or on another substrate.

The pixel has, for example, two operating modes: the storage mode and the readout mode.

During the storage mode, layer 22 is pinned by layers 20 and 24. The reception of light rays by layer 22, through substrate 16 and layers 18 and 20, generates charges in layer 22. This further causes the increase of the Fermi level and of the potential in layer 22. Further, voltage VTX is negative so as to ensure that the generated charges do not pass through layer 26.

During the readout mode, voltage VTX is positive, so that the bipolar transistor turns on and charges are transferred to node 42 and storage area 52.

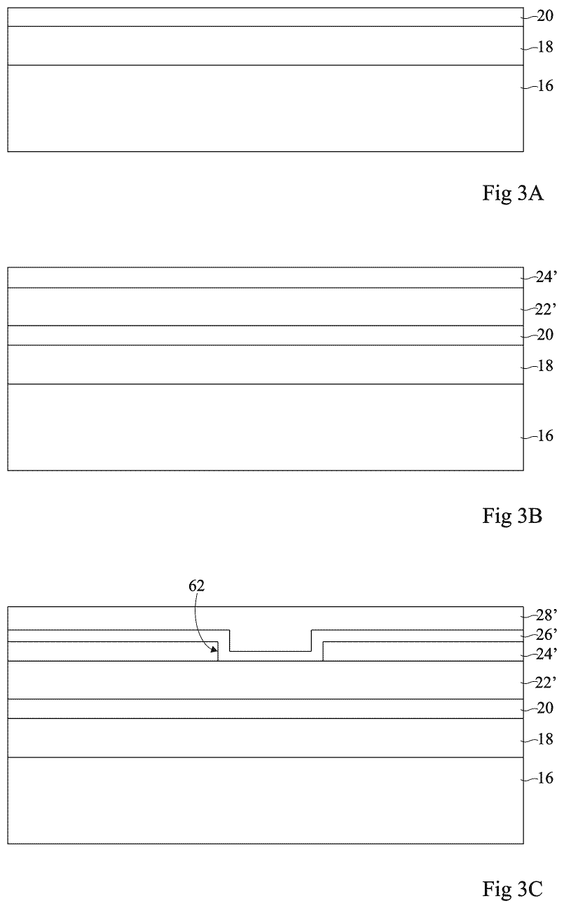

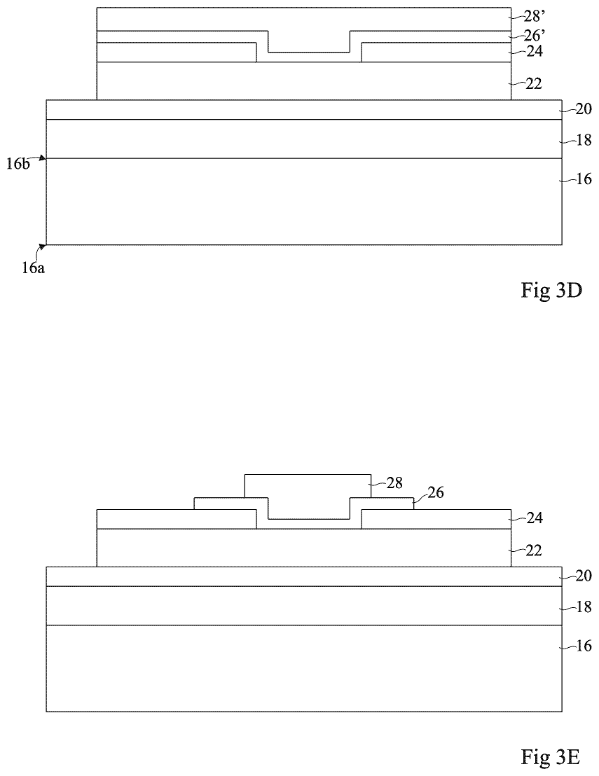

FIGS. 3A to 3E show structures resulting from steps, preferably successive, of a method of manufacturing the device of FIG. 1.

FIG. 3A shows a structure resulting from steps of manufacturing of the device of FIG. 1.

During the step of FIG. 3A, substrate 16 made of a group III-V material, layer 18, and layer 20 are formed. Layer 18 is formed, by an epitaxial growths step, from the upper surface 16b of semiconductor substrate 16. Layer 18 is preferably formed so as to completely cover substrate 16, and more specifically the upper surface of substrate 16. Layer 20 is formed, by an epitaxial growth step, from the upper surface of layer 18. Layer 20 is preferably formed so as to completely cover layer 18 and more specifically the upper surface of layer 18.

FIG. 3B shows a structure resulting from steps of manufacturing of the device of FIG. 1.

During the step of FIG. 3B, layers 22′ and 24′ are formed.

Layer 22′ is made of the same material as the layer 22 of FIG. 1. Layer 22′ has substantially the same thickness as the layer 22 of FIG. 1. Layer 22′ is formed, by an epitaxial growth step, from the upper surface of layer 20. Layer 22′ is preferably formed so as to completely cover layer 20, and more specifically the upper surface of layer 20.

Layer 24′ is made of the same material as the layer 24 of FIG. 1. Layer 24′ has substantially the same thickness as the layer 24 of FIG. 1. Layer 24′ is formed, by an epitaxial growth step, from the upper surface of layer 22′. Layer 24′ is preferably formed so as to completely cover layer 22′, and more specifically the upper surface of layer 24′.

FIG. 3C shows a structure resulting from steps of manufacturing of the device of FIG. 1.

The step of FIG. 3C comprises the forming of an opening 62 in layer 24′. Opening 62 is formed by etching of layer 24′. More specifically, the portion of layer 24′ facing the central portion of layer 22, that is, the portion of layer 22 not covered by layer 24 in FIG. 1, is etched so as to form opening 62.

The step of FIG. 3C further comprises the forming of a layer 26′ and of a layer 28′.

Layer 26′ is made of the same material as the layer 26 of FIG. 1. Layer 26′ has substantially the same thickness as the layer 26 of FIG. 1. Layer 26′ is formed, by an epitaxial growth step, from the bottom and the side walls of opening 62 and the upper surface of layer 24′. Layer 26′ is preferably formed so as to completely cover layer 26′ and the portion of layer 22′ exposed by opening 62. Preferably, layer 26′ is formed conformally. Thus, the upper surface of the portion of layer 26′ located in opening 62 is closer to layer 22′ than the portion of layer 26′ located on layer 24′.

Layer 28′ is made of the same material as the layer 28 of FIG. 1. Layer 28′ has approximately the same thickness as the layer 28 of FIG. 1. Layer 28′ is formed, by an epitaxial growth step, from the upper surface of layer 26′. Layer 28′ is preferably formed so as to completely cover layer 26′, and more specifically the upper surface of layer 26′. Preferably, the upper surface of layer 28′ is planar. Thus, the thickness of layer 28′ is greater at the location opening 62 than elsewhere.

FIG. 3D shows a structure resulting from steps of manufacturing of the device of FIG. 1.

The step of FIG. 3D comprises a step of etching of the stack comprising layers 22′, 24′, 26′, 28′ outside the location of layer 22. In other words, the stack comprising layers 22′, 24′, 26′, 28′ is etched in such a way that layer 22′ is etched and becomes the layer 22 of FIG. 1 and layer 24′ is etched and becomes layer 24. Thus, layer 22 is formed from layer 22′ and layer 24 is formed from layer 24′. Portions of layers 26′ and 28′ not located on layers 22 and 24 are etched.

FIG. 3E shows a structure resulting from steps of manufacturing of the device shown in FIG. 1.

During this step, layer 26′ is etched so as to form layer 26. In other words, the step of FIG. 3E comprises a step of etching of layer 26′ so as to form layer 26. More specifically, this step comprises the etching of layers 26′ and 28′ outside the location of layer 26.

The step of FIG. 3E further comprises a step of etching of layer 28′ so as to form layer 28.

The method of manufacturing the device of FIG. 1 comprises, for example, steps not shown. For example, the method comprises the forming of layer 30 on the structure resulting from the step of FIG. 3E. The method further comprises, for example, the forming of contact pads 32 extending completely through layer 30 to reach layers 24, 26, 28.

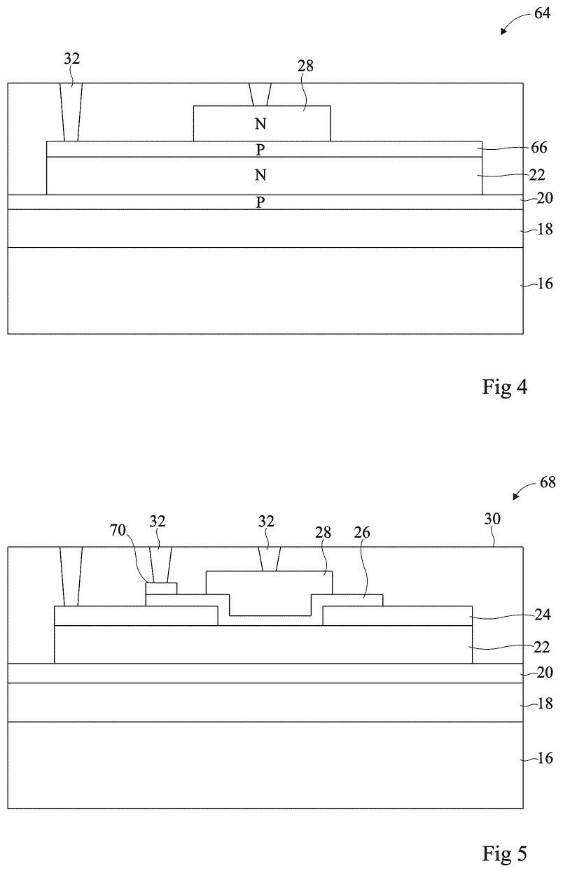

FIG. 4 shows another embodiment of an electronic device comprising a pixel 64.

Pixel 64 comprises elements of the pixel 10 of FIG. 1, arranged and coupled as described in relation with FIG. 1. These elements will not be described in detail again. Thus, pixel 64 comprises substrate 16, buffer layer 18, layer 20 forming the anode of photodiode 12, layer 22 forming the cathode of photodiode 12 and the collector of transistor 14, and layer 28 forming the emitter of transistor 14.

Pixel 64 differs from the pixel 10 of FIG. 1 in that pixel 64 does not comprise layers 24 and 26, but instead comprises a layer 66.

Layer 66 is made of the material of layer 24. Layer 66 has a thickness substantially equal to the thickness of layer 24. The dopant concentration of layer 66 is substantially equal to the dopant concentration of layer 24. Layer 66 at least partially, preferably entirely, covers, and is in contact with, the upper surface of layer 22. For example, layer 66 entirely covers the upper surface of layer 22, except for a portion in contact with a contact pad 32, not shown in FIG. 4. Preferably, layer 66 only covers layer 22. Layer 28 rests on, and is in contact with, the upper surface of layer 66. Preferably, layer 28 only rests on layer 66.

Layer 66 thus corresponds to the base of transistor 12 and enables to pin photodiode 14.

The method of manufacturing pixel 64 differs from the manufacturing method described in relation with FIGS. 3A to 3E, in that the step of FIG. 3C comprises neither the forming of opening 62, nor the forming of layer 26′. Layer 24′ is thus etched, during the step of FIG. 3D, so as to form layer 66. Further, the step of FIG. 3E does not comprise the etching of layer 26′.

FIG. 5 shows another embodiment of an electronic device comprising a pixel 68.

Pixel 68 comprises elements of the pixel 10 of FIG. 1, arranged and coupled as described in relation with FIG. 1. These elements will not be detailed again. Thus, pixel 68 comprises substrate 16, buffer layer 18, layer 20 forming the anode of photodiode 12, layer 22 forming the cathode of photodiode 12, layer 24 pinning photodiode 14, layer 26 forming the base of transistor 12 and the collector of transistor 14, and layer 28 forming the emitter of transistor 14.

Pixel 68 differs from the pixel 10 of FIG. 1 in that pixel 68 comprises a layer 70. Layer 70 is made of a metal oxide, for example made of NiOx. The stoichiometry of NiOx is responsible for its P-type semiconductor behavior, enabling to block electron injection and extraction, in the case where layer 22 is of type N for the storage and the reading of photogenerated electrons. Layer 70 is located on top of, and in contact with, layer 26. Preferably, layer 70 only rests on layer 26. More specifically, layer 70 is located between layer 26 and the contact pad 32 configured to bias layer 26. Preferably, layer 70 is in only contact with said pad 32, layer 26, and layer 30.

In the case of an electron-reading pixel, the material of layer 70 may be replaced by an N-type semiconductor metal oxide having a very high work function, for example higher than 5.5 eV, for example molybdenum oxide (MoOx) or tungsten oxide (WOx).

In the case of a hole-reading pixel, layer 70 is an N-type semiconductor material, for example AZO, ZnO, TiO₂.

Layer 70 enables to decrease risks of charge leakage during the storage mode.

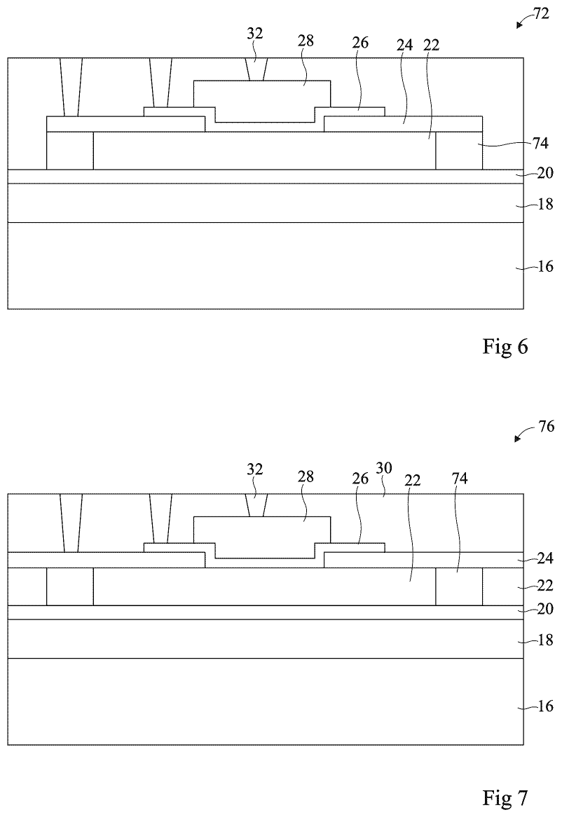

FIG. 6 shows another embodiment of an electronic device comprising a pixel 72.

Pixel 72 comprises elements of the pixel 10 of FIG. 1, arranged and coupled as described in relation with FIG. 1. These elements will not be detailed again. Thus, pixel 72 comprises substrate 16, buffer layer 18, layer 20 forming the anode of photodiode 12, layer 22 forming the cathode of photodiode 12, layer 24 pinning photodiode 14, layer 26 forming the base of transistor 12, the collector of transistor 14, and layer 28 forming the emitter of transistor 14.

Pixel 72 differs from the pixel 10 of FIG. 1 in that the periphery of the layer 22 of pixel 72 is replaced by a passivation region 74. Region 74 is made of the same material as layer 22, for example a group III-V semiconductor material. Region 74 is, for example, doped with zinc atoms, for example obtained by diffusion, or beryllium atoms, for example obtained by implantation. Region 74 extends from layer 20 to layer 24. Region 74 separates, preferably entirely, layer 74 from layer 30. Thus, layer 22 is not in contact with layer 30.

FIG. 7 shows another embodiment of an electronic device comprising a pixel 76.

Pixel 76 comprises elements of the pixel 72 of FIG. 6, arranged and coupled as described in relation with FIG. 6. These elements will not be detailed again. Thus, pixel 76 comprises substrate 16, buffer layer 18, layer 20 forming the anode of photodiode 12, layer 22 forming the cathode of photodiode 12, layer 24 pinning photodiode 14, layer 26 forming the base of transistor 12, the collector of transistor 14, layer 28 forming the emitter of transistor 14, and passivation region 74.

Pixel 76 differs from the pixel 72 of FIG. 6 in that layer 22 extends outside pixel 76. More precisely, layer 22 is, for example, common to a plurality of neighboring pixels, the portion of layer 22 corresponding to a pixel being separated from the rest of layer 22 by region 74. Similarly, layer 66 is common to a plurality of pixels.

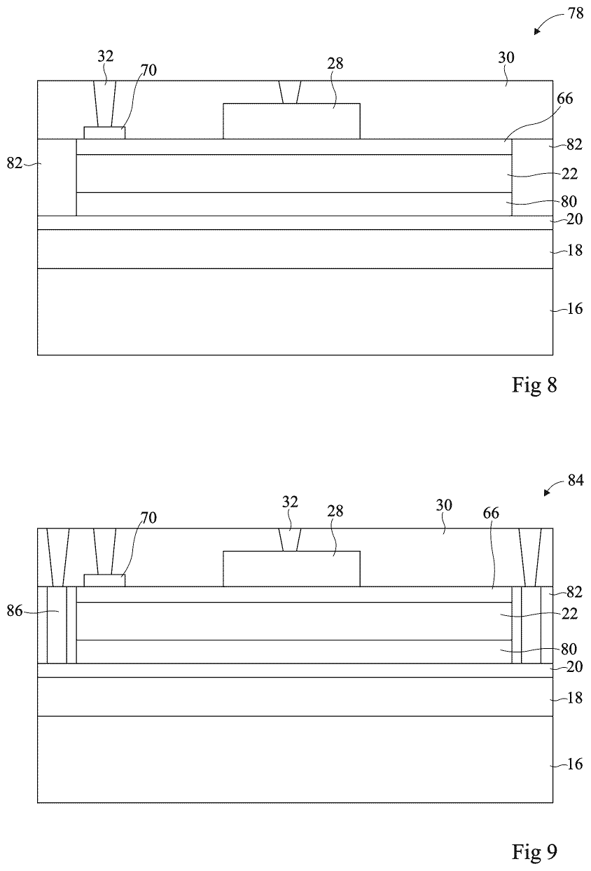

FIG. 8 shows another embodiment of an electronic device comprising a pixel 78.

Pixel 78 comprises elements of the pixel 64 of FIG. 4, arranged and coupled as described in relation with FIG. 4. These elements will not be detailed again. Thus, pixel 78 comprises substrate 16, layer 20, layer 22, layer 66, layer 28, layer 70, layer 30, and pads 32. Pixel 78 also comprises, for example, buffer layer 18.

Pixel 78 differs from the pixel 64 of FIG. 4 in that pixel 78 comprises the layer 70 of the pixel 68 of FIG. 5.

Pixel 78 further differs from the pixel 64 of FIG. 4 in that pixel 78 comprises an absorption layer 80. Layer 80 covers layer 20. Layer 80 preferably covers layer 20 only. Layer 80 preferably partially covers layer 20. Layer 80 has, for example, horizontal dimensions identical to those of layer 22. Preferably, layers 80, 22, and 66 have coplanar side walls. Layer 80 is made of the same material as layer 20. Preferably, the material of layer 80 has the same lattice parameter as layer 22. Layer 80 is doped with the same conductivity type as layer 20. The dopant concentration of layer 80 is, for example, different from the dopant concentration of layer 20. The dopant concentration of layer 20 is higher than that of layer 80. Layer 80 enables, due to its doping, to more tightly pin layer 20, and thus to decorrelate the storage capacity, which increases as the pinned layer becomes thinner, from the quantum efficiency, which increases as the pinned layer becomes thicker but which actually decreases the storage capacity.

Layer 80 is formed by an epitaxial growth step, for example between the forming of layer 20 and the forming of layer 22. Layer 80 is also, for example, partially etched with layers 22 and 66.

Pixel 78 further differs from the pixel 64 of FIG. 4 in that pixel 78 comprises a region 82 of charged oxide. Region 82 is located at the same positions as the region 74 of FIGS. 6 and 7, that is, extending laterally around the stack of layers 80, 22, 66. Region 82 thus extends from the upper surface of layer 20 to the upper surface of layer 66.

As a variant, layer 80 may more widely cover layer 20, for example completely cover layer 20. In this case, layer 80 is not etched along with layers 22 and 66.

FIG. 9 shows another example of an electronic device comprising a pixel 84.

Pixel 84 comprises elements of the pixel 78 of FIG. 8, arranged and coupled as described in relation with FIG. 8. These elements will not be detailed again. For example, pixel 84 comprises substrate 16, layer 20, layer 80, layer 22, layer 66, layer 28, layer 70, layer 30, pads 32, and regions 82. Pixel 84 also comprises, for example, buffer layer 18.

Pixel 84 differs from the pixel 78 of FIG. 8 in that pixel 84 comprises a conductive wall 86. Wall 86 extends in region 82. Wall 86 extends from the upper surface of region 82 to the lower surface of region 82. Thus, wall 86 is in contact, by a lower end, with layer 20. Wall 86 is laterally surrounded by region 86. Thus, the sides of wall 86 are covered by region 86. Wall 86 is thus separated from the stack of layers 80, 22 and 66 by a portion of region 82. Wall 86 preferably surrounds the stack of layers 80, 22, 66.

Wall 86 is preferably biased. For example, wall 86 is in contact with a pad 32 running through layer 30. Wall 86 receives, preferably from pad 32, a bias voltage. The voltage applied to wall 86 enables to form an electrical passivation of the pixel edges.

As a variant, wall 86 may be located in the region 74 of the embodiment of FIG. 6 or 7.

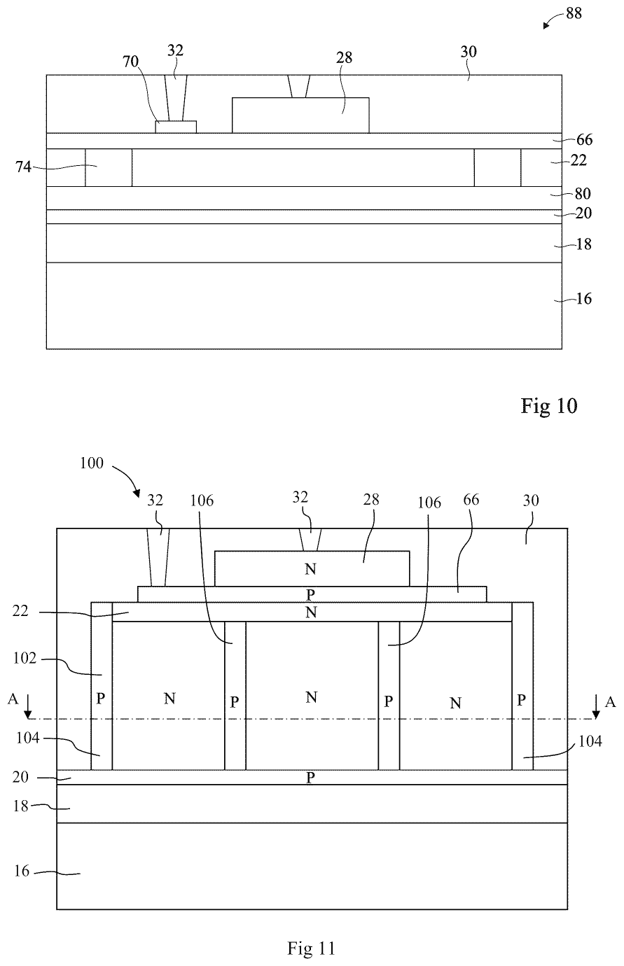

FIG. 10 shows another embodiment of an electronic device comprising a pixel 88.

Pixel 88 comprises elements of the pixel 84 of FIG. 9, arranged and coupled as described in relation with FIG. 9. These elements will not be detailed again. Thus, pixel 88 comprises substrate 16, layer 20, layer 80, layer 22, layer 66, layer 28, layer 70, layer 30, pads 32, and regions 82. Pixel 88 also comprises, for example, buffer layer 18.

Pixel 88 differs from pixel 84 in that the layer 80 of pixel 88 covers layer 20, preferably entirely layer 20.

Pixel 88 differs from pixel 84 in that pixel 88 comprises the regions 74 described in relation with FIG. 7, arranged as described in relation with FIG. 7. Thus, layer 22 extends outside pixel 88. More specifically, layer 22 is, for example, common to a plurality of neighboring pixels, the portion of layer 22 corresponding to a pixel being separated from the rest of layer 22 by region 74. Similarly, layer 66 and layer 80 are, for example, common to a plurality of pixels.

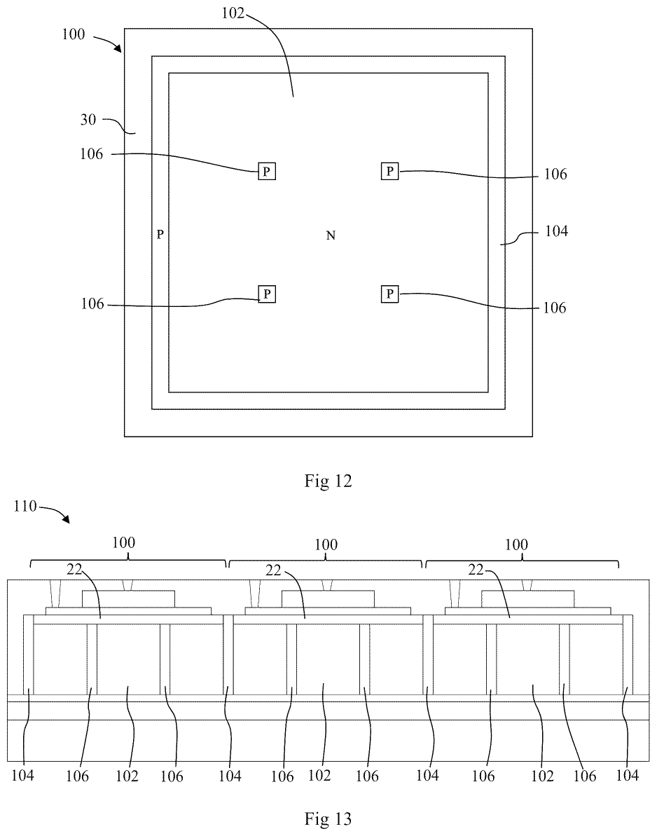

FIG. 11 shows another embodiment of an electronic device comprising a pixel 100. FIG. 12 is a cross-section view of FIG. 11 according to plane A-A.

Pixel 100 comprises elements of the pixel 64 of FIG. 4, arranged and coupled as described in relation with FIG. 4. These elements will not be detailed again. Thus, pixel 100 comprises substrate 16, layer 20, layer 66, layer 28, layer 70, layer 30, and pads 32. Pixel 100 for example also comprises buffer layer 18.

Pixel 100 differs from the pixel 64 of FIG. 4 in that pixel 100 comprises a layer 102 between layer 22 and layer 20, a wall 104 surrounding layers 22 and 102, and pillars 106 crossing through layer 102.

Layer 102 is made of a photosensitive semiconductor material, for example of the same material as layer 22. Layer 102 is configured to be photosensitive to a specific operating wavelength range. Layer 102 is, for example, an epitaxial layer. Layer 102 covers, and is preferably in contact with, the upper surface of layer 20. Layer 22 covers, and is preferably in contact with, the upper surface of layer 102. Layer 102 is doped with a second conductivity type, opposite to the first conductivity type, for example type N. For example, the doping concentration of layer 102 is in the range from 10¹⁵ atoms/cm³ to 10¹⁷ atoms/cm³.

The thickness of the layer 102 is in the range from 500 nm to 3 μm to maximize the quantum efficiency of the device. The width of the region 102, measured in a plane parallel to the upper face of the region 102 is in the range from 1 μm to 5 μm. The aspect ratio of the region 102, that is the ratio between the width of the region 102 and the thickness of the region 102 is in the range from 1 to 5. The cross-section of the region 102, seen in a plane parallel to the upper face of the region 102, for example has an oval, circular, or polygonal shape, particularly triangular, rectangular, square, or hexagonal.

Wall 104 is made of a semiconductor material, for example of the same material as layer 20. Wall 104 is, for example, made from an epitaxial layer. Wall 104 is preferably in contact with the lateral surface of layer 22 and with the lateral surface of layer 102. Wall 104 20 preferably entirely covers the lateral surface of layer 22 and the lateral surface of layer 102. Wall 104 is doped with the first conductivity type, for example type P. Wall 104 is heavily doped. For example, the dopant concentration of wall 104 is greater than 10¹⁷ atoms/cm³. The thickness of the wall 104, measured in a plane parallel to the upper face of the region 102 is in the range from 10¹⁷ atoms/cm³ to 10²¹ atoms/cm³.

Each pillar 106 is made of a semiconductor material, for example of the same material as layer 102. Each pillar 106 is, for example, made from an epitaxial layer. Each pillar 106 is preferably in contact with the upper surface of layer 20 and the lower surface of layer 22, that is to say that each pillar 106 extends across the entire thickness of layer 102. Each pillar 106 is doped with the first conductivity type, for example type P. Each pillar 106 is heavily doped. For example, the dopant concentration of each pillar 106 is greater than 10¹⁷ atoms/cm³. The number of pillars 106 in the layer 102 is superior or equal to one. As an example, the number of pillars 106 in the layer 102 is equal to four.

The height of the pillar 106 is preferably equal to the height of the region 12. The thickness of the pillar 106, measured in a plane parallel to the upper face of the region 102 is in the range from 100 nm to 400 nm. The cross-section of the pillar 106 for example has an oval, circular, or polygonal shape, particularly triangular, rectangular, square, or hexagonal.

As a variation, pillar 106 and wall 140 can be a vertical stack made of a thin gate oxide and a second oxide presenting a fixed density of charges at their interface in order to deplete region 102 using the electric field induced by the fixed charges.

As a variation, the layer 66 can be replaced by the layers 24 and 26 shown in FIG. 1. As a variation, the pixel 100 can comprise the layer 70 shown in FIG. 8 between the layer 66 and the respective conductive pad 32.

FIG. 13 shows an embodiment of an electronic device 110 comprising several pixels 100 as shown in FIG. 11. The walls 104 separate the layers 22 and 102 of two adjacent pixels 110.

First and second simulations were made.

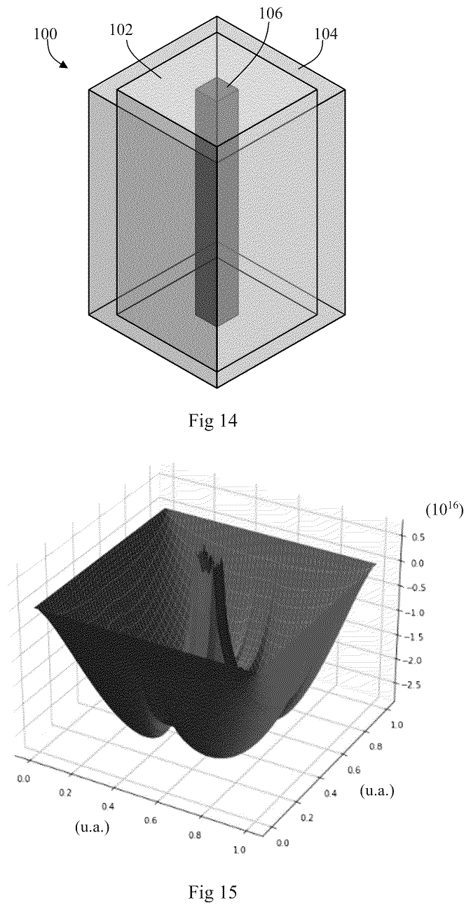

FIG. 14 and FIG. 17 are perspective views with transparence of the pixel 100 used respectively for the first and second simulations. For the first simulation, the pixel 100 comprises a single pillar 106. For the second simulation, the pixel 100 comprises four pillars 106.

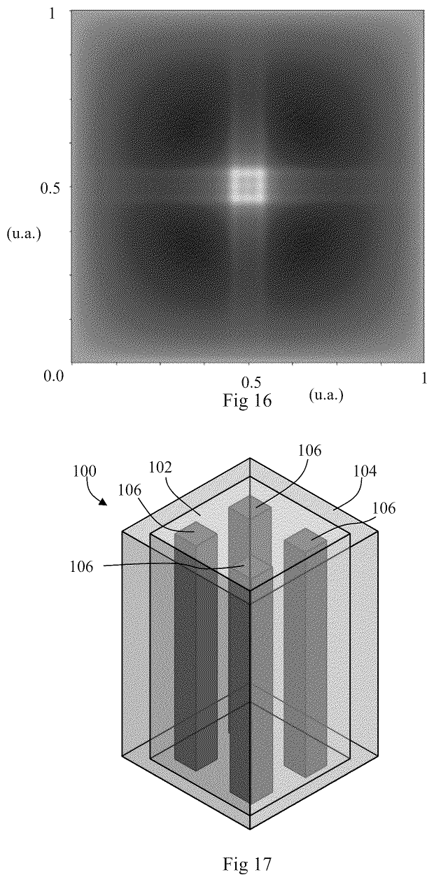

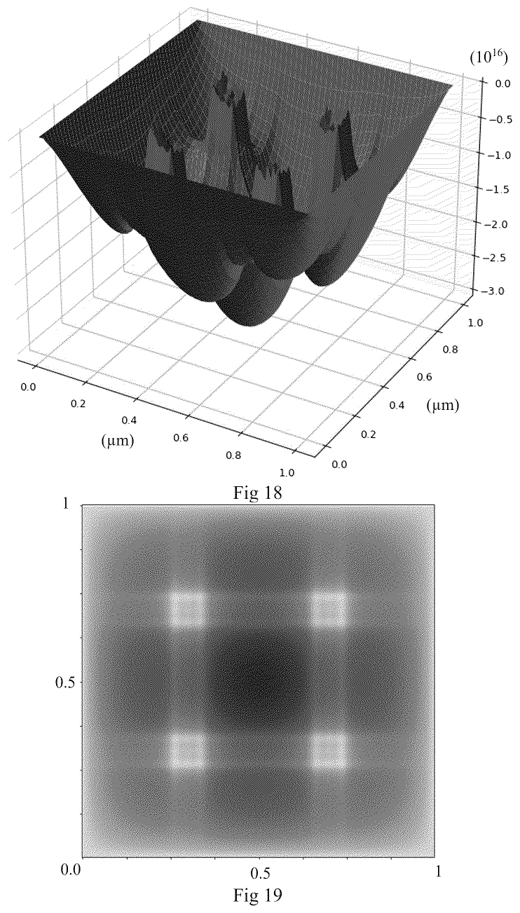

FIG. 15 and FIG. 18 are three dimensional views showing the evolution of the electrostatic potential in the region 102 of the pixel 100 in a plane parallel to the upper and lower faces of the region 102, for example at mid-distance from the upper and lower faces of the region 102, respectively for the first and second simulations.

FIG. 16 and FIG. 19 are top views showing, in light intensity level, the evolution of the electrostatic potential in the region 102 of the pixel 100 in a plane parallel to the upper and lower faces of the region 102 respectively for the first and second simulations.

The pillars 106 allow to deplete the region 102 of the pixel 100 even when the aspect ratio of the region 102 is high. The walls 104 allow to isolate the region 102 of one pixel 100 from the region 102 of an adjacent pixel 100.

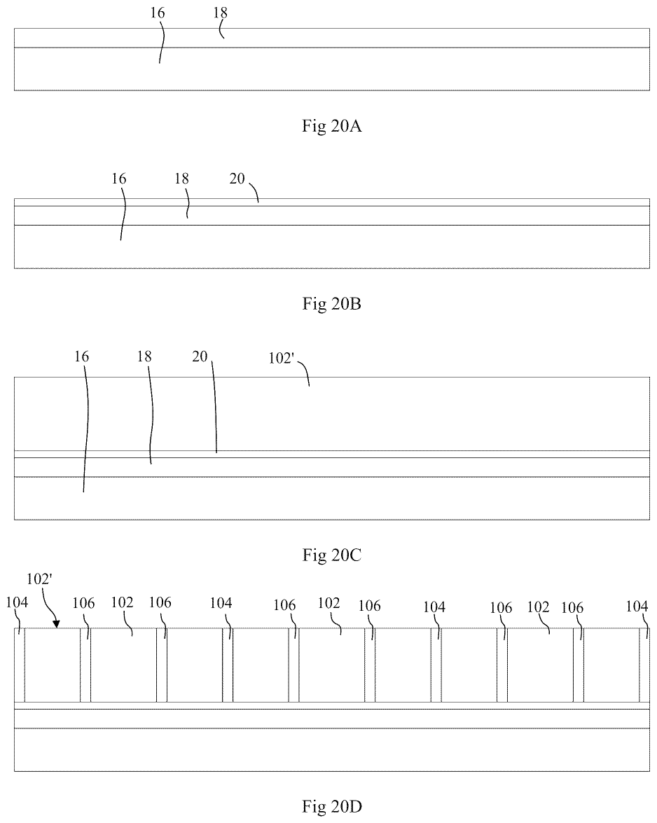

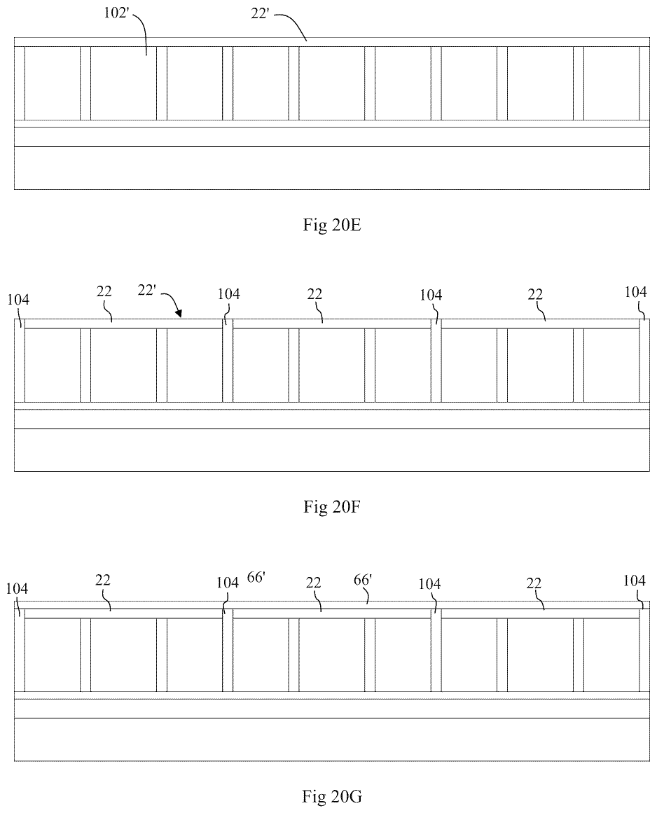

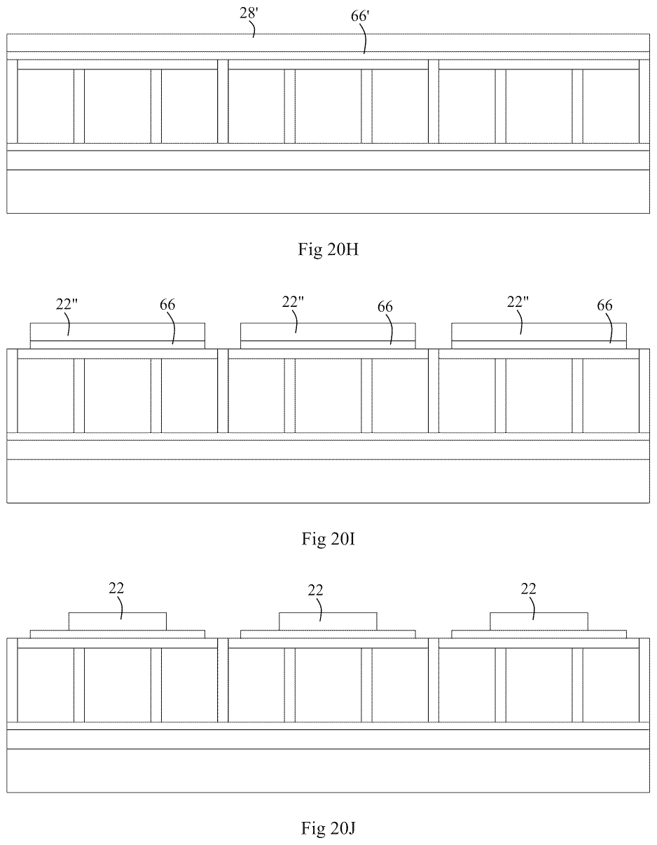

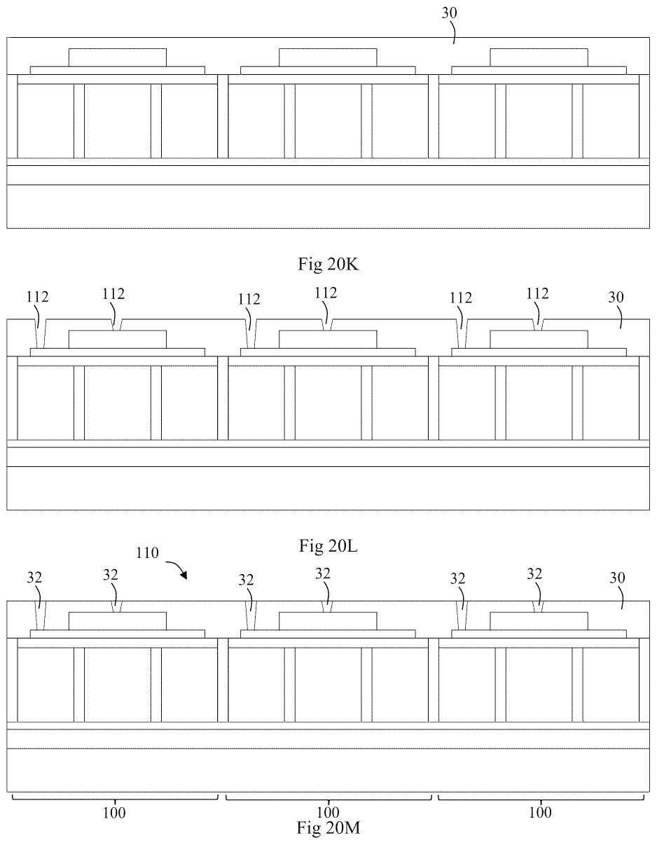

FIGS. 20A to 20M show structures resulting from steps, preferably successive, of a method of manufacturing the device 110 of FIG. 13.

FIG. 20A shows a structure resulting from the manufacture of layer 18 on substrate 16. Layer 18 is formed, by an epitaxial growth step, from the upper surface of semiconductor substrate 16. Layer 18 is preferably formed so as to completely cover substrate 16, and more specifically the upper surface of substrate 16.

FIG. 20B shows a structure resulting from the manufacture of layer 20 on layer 18. Layer 20 is formed, by an epitaxial growth step, from the upper surface of layer 18. Layer 20 is preferably formed so as to completely cover layer 18 and more specifically the upper surface of layer 18.

FIG. 20C shows a structure resulting from the manufacture of a layer 102′ on layer 20. Layer 102′ is made of the same material as the layers 102 of FIG. 13. Layer 102′ has substantially the same thickness as the layers 102 of FIG. 13. Layer 102′ is formed, by an epitaxial growth step, from the upper surface of layer 20. Layer 102′ is preferably formed so as to completely cover layer 20, and more specifically the upper surface of layer 20.

FIG. 20D shows a structure resulting from the manufacture of walls 104 and pillars 106 in layer 102′. Walls 104 and pillars 106 are manufactured by a diffusion step or an implantation step of P-type dopants in layer 102′. As an example, walls 104 and pillars 106 are manufactured by a diffusion step of Zinc (Zn) or by an implantation step of Beryllium (Be) in layer 102′. The layers 102 are then delimited in layer 102′ and separated by walls 104.

FIG. 20E shows a structure resulting from the manufacture of a layer 22′ on layer 102′. Layer 22′ is made of the same material as the layer 22 of FIG. 13. Layer 22′ has substantially the same thickness as the layer 22 of FIG. 13. Layer 22′ is formed, by an epitaxial growth step, from the upper surface of layer 102′. Layer 22′ is preferably formed so as to completely cover layer 102′, and more specifically the upper surface of layer 102′.

FIG. 20F shows a structure resulting from the manufacture of walls 104 in layer 22′. Walls 104 are manufactured by a diffusion step or an implantation step of P-type dopants in layer 22′. As an example, walls 104 are manufactured by a diffusion step of Zinc (Zn) or by an implantation step of Beryllium (Be) in layer 22′. The layers 22 are then delimited in layer 22′ and separated by walls 104.

FIG. 20G shows a structure resulting from the manufacture of a layer 66′on layers 22 and walls 104. Layer 66′ is made of the same material as the layer 66 of FIG. 13. Layer 66′ has substantially the same thickness as the layer 66 of FIG. 13. Layer 66′ is formed, by an epitaxial growth step, from the upper surface of layers 22 and walls 104. Layer 66′ is preferably formed so as to completely cover layers 22 and walls 104, and more specifically the upper surfaces of layers 22 and walls 104.

FIG. 20H shows a structure resulting from the manufacture of a layer 28′ on layer 66′. Layer 28′ is made of the same material as the layer 28 of FIG. 13. Layer 28′ has substantially the same thickness as the layer 28 of FIG. 13. Layer 28′ is formed, by an epitaxial growth step, from the upper surface of layer 66′. Layer 28′ is preferably formed so as to completely cover layer 66′, and more specifically the upper surface of layer 66′.

FIG. 20I shows a structure resulting from a step of etching of the stack comprising layers 22′ and 66′ to delimit the layers 66 in layer 66′ and to delimit layers 22″ in layer 22′.

FIG. 20J shows a structure resulting from a step of etching the layers 22″ to delimit the layers 22.

FIG. 20K shows a structure resulting from a step of forming of layer 30 on the structure resulting from the step of FIG. 20J.

FIG. 20L shows a structure resulting from a step of forming openings 112 in layer 30 at the locations of contact pads 32.

FIG. 20M shows a structure resulting from a step of forming contact pads 32. The device 110 comprising several pixels 100 is then obtained.

In the embodiment previously disclosed in relation to FIGS. 20A to 20M, walls 104 and pillars 106 are made in a single step of diffusion/implantation. As a variation, walls 104 and pillars 106 can be made by several steps of diffusion/implantation. As an example, an embodiment is now described in which walls 104 and pillars 106 are made by three steps of diffusion/implantation.

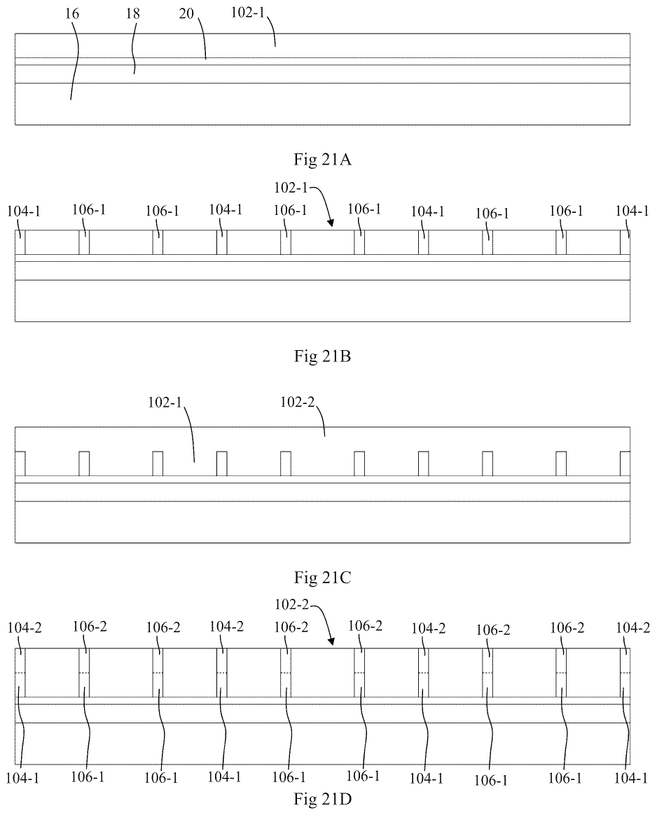

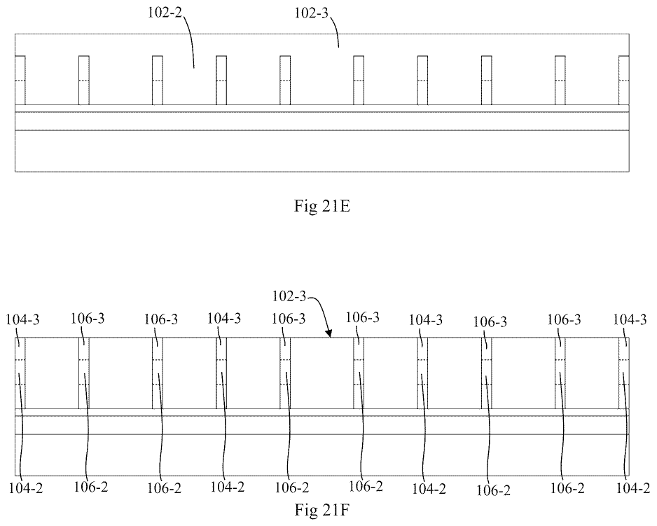

FIGS. 21A to 21F show structures resulting from steps, preferably successive, of another method of manufacturing the walls 104, the pillars 106, and the layers 102 of device 110 of FIG. 13.

FIG. 21A shows a structure resulting from the manufacture of a stack comprising, on substrate 16, layer 18, layer 22, and a layer 102-1. Layer 102-1 is made of the same material as the layer 102 of FIG. 13. Layer 102-1 has a thickness inferior to the thickness of layer 102 of FIG. 13. Layer 102-1 is formed, by an epitaxial growth step, from the upper surface of layer 20. Layer 102-1 is preferably formed so as to completely cover layer 20, and more specifically the upper surface of layer 20.

FIG. 21B shows a structure resulting from the manufacture of a first part 104-1 of each wall 104 and a first part 106-1 of each pillar 106 in layer 102-1. The first parts of walls 104-1 and pillars 106-1 are manufactured by a diffusion step or an implantation step of P-type dopants in layer 102-1. As an example, the first parts of walls 104-1 and pillars 106-1 are manufactured by a diffusion step of Zinc (Zn) or by an implantation step of Beryllium (Be) in layer 102-1.

FIG. 21C shows a structure resulting from the manufacture of a layer 102-2 on layer 102-1. Layer 102-2 is made of the same material as the layer 102 of FIG. 13. Layer 102-2 has a thickness inferior to the thickness of layer 102 of FIG. 13. Layer 102-2 is formed, by an epitaxial growth step, from the upper surface of layer 102-1. Layer 102-2 is preferably formed so as to completely cover layer 102-1, and more specifically the upper surface of layer 102-1.

FIG. 21D shows a structure resulting from the manufacture of a second part 104-2 of each wall 104 and a second part 106-2 of each pillar 106 in layer 102-2. The first parts of walls 104-2 and pillars 106-2 are manufactured by a diffusion step or an implantation step of P-type dopants in layer 102-2. As an example, the first parts of walls 104-2 and pillars 106-2 are manufactured by a diffusion step of Zinc (Zn) or by an implantation step of Beryllium (Be) in layer 102-2. The second parts of the walls 104-2 are made in line with the first parts of the walls 104-1 and the second parts of the pillars 106-2 are made in line with the first parts of the pillars 106-1.

FIG. 21E shows a structure resulting from the manufacture of a layer 102-3 on layer 102-2. Layer 102-3 is made of the same material as the layer 102 of FIG. 13. Layer 102-3 has a thickness inferior to the thickness of layer 102 of FIG. 13. The sum of the thicknesses of the layers 102-1, 102-2, and 102-3 is substantially equal to the thickness of layer 102. Layer 102-3 is formed, by an epitaxial growth step, from the upper surface of layer 102-2. Layer 102-3 is preferably formed so as to completely cover layer 102-2, and more specifically the upper surface of layer 102-2.

FIG. 21F shows a structure resulting from the manufacture of a third part 104-3 of each wall 104 and a third part 106-3 of each pillar 106 in layer 102-3. The first parts of walls 104-3 and pillars 106-3 are manufactured by a diffusion step or an implantation step of P-type dopants in layer 102-3. As an example, the first parts of walls 104-3 and pillars 106-3 are manufactured by a diffusion step of Zinc (Zn) or by an implantation step of Beryllium (Be) in layer 102-3. The third parts of the walls 104-3 are made in line with the second parts of the walls 104-2 and the third parts of the pillars 106-3 are made in line with the second parts of the pillars 106-2.

Walls 104 are formed by the stack of the first parts of walls 104-1, the second parts of walls 104-2, and the third parts of walls 104-3. Pillars 106 are formed by the stack of the first parts of pillars 106-1, the second parts of pillars 106-2, and the third parts of pillars 106-3. First layers 102 are formed by the stack of the portions of layers 102-1, 102-2, and 102-3 delimited by walls 104.

An advantage of the described embodiments is that they enable to form a photodiode on a III-V material, while avoiding thermal noise caused by charge transfer and dark currents.

Another advantage of the described embodiments is that they enable to more easily integrate a transfer transistor with a photodiode formed on a III-V material.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An optoelectronic device comprising a pixel, the pixel comprising:
a first semiconductor substrate made of a group III-V material;
a first doped semiconductor layer supported by the first semiconductor substrate;
a pinned photodiode;
a bipolar transfer transistor;
wherein the first doped semiconductor layer forms both a collector of the bipolar transfer transistor and a cathode of the pinned photodiode;
a second doped semiconductor layer located between the first semiconductor substrate and the first doped semiconductor layer, wherein the second doped semiconductor layer forms an anode of the pinned photodiode; and
a third doped semiconductor layer having a same conductivity type as the second doped semiconductor layer, wherein the third doped semiconductor layer forms a base of the bipolar transfer transistor, and wherein the first doped semiconductor layer is located between the second doped semiconductor layer and the third doped semiconductor layer.

2. The device according to claim 1, wherein the first doped semiconductor layer is in contact with a first surface of the second doped semiconductor layer.

3. The device according to claim 1, further comprising a fourth doped semiconductor layer more heavily doped than the second doped semiconductor layer, wherein the fourth doped semiconductor layer is in contact with a peripheral portion of a first surface of the first doped semiconductor layer and does not cover a central portion of the first surface of the first doped semiconductor layer, and wherein the third doped semiconductor layer is contact with the central portion of the first surface of the first doped semiconductor layer.

4. The device according to claim 3, further comprising a fifth doped semiconductor layer resting on the third doped semiconductor layer, wherein the fifth doped semiconductor layer is separated from the first doped semiconductor layer at the central portion of the first surface of the first doped semiconductor layer by the third doped semiconductor layer, wherein the fifth doped semiconductor layer forms an emitter of the bipolar transfer transistor.

5. The device according to claim 1, further comprising a passivation region made of one of a charged oxide or a semiconductor material doped with zinc atoms or beryllium atoms, the passivation region surrounding the first doped semiconductor layer.

6. The device according to claim 5, wherein the device comprises a plurality of pixels, the first doped semiconductor layer being common to each pixel of the plurality of pixels, and wherein portions of the first doped semiconductor layer corresponding to each pixel are separated by the passivation region.

7. The device according to claim 5, further comprising a wall extending in the passivation region, wherein the wall surrounds the first doped semiconductor layer, and wherein the wall is configured to be biased.

8. The device according to claims 1, further comprising a layer made of NiOx located between the third doped semiconductor layer and a contact pad.

9. The device according to claim 1, further comprising a control circuit configured to control the pixel, wherein the bipolar transfer transistor is a transfer transistor of said control circuit.

10. The device according to claim 9, further comprising a second semiconductor substrate on top and inside of which transistors of the control circuit are formed, wherein the first and second semiconductor substrates are bonded to each other by molecular bonding.

11. The device according to claim 1, wherein the third doped semiconductor layer is configured to receive a negative voltage in storage mode, and wherein the third doped semiconductor layer is configured to receive a positive voltage in readout mode.

12. An optoelectronic device comprising a pixel, the pixel comprising a pinned photodiode and a bipolar transfer transistor, the photodiode and the bipolar transfer transistor being formed inside and on top of a same first semiconductor substrate made of a III-V material, wherein a same first doped semiconductor layer forms a collector of the bipolar transfer transistor and a cathode of the pinned photodiode.

13. The device according to claim 12, wherein the transistor comprises a second layer forming a base, and a doped third layer of the same conductivity type as the second layer, the first layer being located between the second and third layers, the second layer resting on a first surface of the first layer.

14. The device according to claim 13, wherein the base of the bipolar transfer transistor comprises a fourth layer more heavily doped than the second layer, the fourth layer covering a peripheral portion of the first surface of the first layer and not covering a central portion of the first surface of the first layer, the second layer covering the central portion of the first surface of the first layer.

15. The device according to claim 14, wherein the pixel comprises a fifth layer resting on the first layer, the fifth layer being separated from the first layer by the second layer, the fifth layer forming an emitter of the bipolar transfer transistor and the first layer forming the collector of the bipolar transfer transistor.

16. The device according to claim 13, wherein the pixel comprises a passivation region made of charged oxide or of a semiconductor material doped with zinc atoms or beryllium atoms, the region surrounding the first layer.

17. The device according to claim 16, wherein the device comprises at least two pixels, the first layer being common to a plurality of pixels, the portions of the first layer corresponding to each pixel being separated by passivation regions.

18. The device according to claim 16, wherein the pixel comprises a wall extending in the passivation region, so as to surround the second region, the wall being configured to be biased.

19. The device according to claim 13, wherein the base of the bipolar transfer transistor comprises a seventh doped layer of the same conductivity type as the second layer, the seventh layer being located between the second and third layers, and a doped third layer, the seventh layer being crossed by doped pillars of the same conductivity type as the third layer or by oxide pillars having a fixed density of charges and acting as MOS capacitors.

20. The device according to claim 19, wherein the seventh layer is surrounded by a doped wall of the same conductivity type as the third layer.

21. The device according to claim 19, wherein the seventh layer is surrounded by a vertical oxide stack having a fixed density of charges and acting as a MOS capacitor.

22. The device according to claim 21, wherein the first layer is surrounded by the wall.

23. The device according to claim 1, wherein the pixel comprises a sixth layer made of NiOx located between the second layer and a contact pad.

24. The device according to claims 1, further comprising a circuit for controlling the pixel, the bipolar transfer transistor being a transfer transistor of said control circuit.

25. The device according to claim 24, further comprising a second semiconductor substrate on top and inside of which transistors of the pixel control circuit are formed, the first and second substrates being bonded to each other by molecular bonding.

26. The device according to claim 1, further comprising a storage mode, and wherein the second layer is configured to receive a negative voltage, and a readout mode, and wherein the second layer is configured to receive a positive voltage.
